(19) United States
(12) Patent Application Publication
(10) Pub. No.: US 2025/0219344 A1
(43) Pub. Date: Jul. 3, 2025

(54) ELECTRICAL CONNECTOR STRUCTURE, TERMINAL MODULE AND TERMINAL MODULE MANUFACTURING METHOD

(71) Applicant: Li Hong TECHNOLOGY SOLUTIONS CO., LTD., TAOYUAN CITY (TW)

(72) Inventor: Cheng-yang LI, TAOYUAN CITY (TW)

(21) Appl. No.: 18/991,868

(22) Filed: Dec. 23, 2024

(30) Foreign Application Priority Data
Dec. 29, 2023 (TW) 112151552

(51) Int. Cl. H01R 43/16; H01R 12/70; H01R 12/88

(52) U.S. Cl. CPC H01R 43/16; H01R 12/7076; H01R 12/88

(57) ABSTRACT

An electrical connector structure, a terminal module and a terminal module manufacturing method are disclosed. The electrical connector structure is configured to connect an optoelectronic transceiver module to a motherboard. The electrical connector structure includes an intermediate board module and a fixing structure. The terminal modules of the intermediate board module are arranged side by side. The terminal module includes a plurality of terminals and a terminal base. The terminal base covers the terminals. Each of the terminals includes a root portion, a first terminal arm and a second terminal arm. The root portion is covered by the terminal base, and an end portion of the first terminal arm and an end portion of the second terminal arm extend out of the terminal base.

### CROSS REFERENCE TO RELATED APPLICATIONS

This application claims priority to Taiwan Patent Application No. 112151552, filed Dec. 29, 2023, the disclosure of which is incorporated herein by reference in its entirety.

### FIELD OF ART

The present application relates to a connector field, and more specifically to an electrical connector structure configured to connect an optoelectronic transceiver module to a motherboard, and a terminal module manufacturing method.

### BACKGROUND OF DISCLOSURE

An inevitable trend in the future is to use photons instead of electrons for computation in an integrated circuit, and to use light as data transmission to meet a demand for high-capacity and high-speed signal transmission. At present, an optical electronic integrated circuit has been developed, and an optoelectronic transceiver component has been formed by a co-packaged technology and are suitable for high-performance data exchange, long-distance interconnection, 5G facilities, computing equipment, and etc. However, nowadays the co-packaged optical transceiver component must be connected to a motherboard through connecting wires and connectors, which leads to a long signal transmission path and affects transmission efficiency. So it is difficult to fully utilize high transmission bandwidth density and high speed characteristics of the co-packaged optical transceiver component, and difficult to repair and replace. In view of this, how to improve the connection between the co-packaged optical transceiver component and the motherboard is an urgent issue that needs to be addressed.

Moreover, in the prior art, as shown in FIG. 17, terminals of a connector are usually made by etching. Generally speaking, a process of etching the terminals roughly includes multiple steps such as metal etching, degreasing, water washing, etching, and drying. Furthermore, if the terminals are manufactured by etching, it will be difficult to adjust the number of the terminals and causes many inconveniences.

Furthermore, in the existing manufacturing processes, the printed circuit board and the etched terminals need to be bonded together to form a stacked structure, which is very labor-intensive. And, in the existing manufacturing processes, due to the need for etching, it is also necessary to consider the adaptability of photomasks, the printed circuit board, and etc., which increases the design difficulty of the manufacturing process. On average, it takes about 4 to 6 months to mass produce products, which is very time-consuming and causes many problems.

### BRIEF SUMMARY OF DISCLOSURE

One object of the present application is to provide an electrical connector structure that can fully utilize advantages of high-capacity and high-speed transmission provided by an optoelectronic transceiver module, and shorten transmission distance between the optoelectronic transceiver module and a motherboard.

Another object of the present application is to provide a terminal module that is small in size and can be assembled and arranged side by side to improve terminal density.

Another object of the present application is to provide a terminal module manufacturing method, which has advantages of stable terminal size, high precision, fast production, and convenient terminal storage and protection.

Other objects and advantages of the present application may be further understood from technical features disclosed by the present application.

Based on the above objects, the present application provides a terminal module manufacturing method, which comprises:
providing a material strip;
forming a plurality of terminals and at least one material strip fixing portion on the material strip by a stamping process; wherein the plurality of terminals is connected to the at least one material strip fixing portion; and
forming a terminal base on the plurality of terminals, and then detaching the plurality of terminals from the at least one material strip fixing portion; or
detaching the plurality of terminals from the at least one material strip fixing portion, and then forming the terminal base on the plurality of terminals.

Preferably, the terminal base is made of plastic; and the terminal module manufacturing method further comprises: disposing the plurality of terminals and the at least one material strip fixing portion in a plastic molding machine to form the terminal base.

Preferably, the material strip defines a plurality of stamping regions; and the terminal module manufacturing method further comprises: forming the plurality of terminals in each of the plurality of stamping regions, wherein the plurality of terminals between the plurality of stamping regions are connected by a first connection part.

Preferably, the terminal module manufacturing method further comprises: after forming the terminal base on the plurality of terminals, cutting the first connection part and a connection between the plurality of terminals and the at least one material strip fixing portion.

Preferably, the terminal module manufacturing method further comprises: according to a predetermined number, cutting the first connection part and removing unnecessary of the terminals by laser to obtain the plurality of terminals having the predetermined number being connected to each other.

Preferably, the terminal base forms a plurality of holes, which are located between the plurality of terminals connected to each other; and the terminal module manufacturing method further comprises: cutting a plurality of second connection parts connected between the plurality of terminals in the same stamping region through the plurality of holes by a laser cutting process.

Preferably, the material strip defines a plurality of stamping regions; and the terminal module manufacturing method further comprises: forming the plurality of terminals in the plurality of stamping regions respectively.

Preferably, the terminal module manufacturing method further comprises: detaching the plurality of terminals from the at least one material strip fixing portion, and then employing the plastic molding machine to form the terminal base on the plurality of terminals spaced apart from each other.

Based on the above objects, the present application further provides a terminal module, which comprises a plurality of terminals and a terminal base covering the plurality of terminals. Wherein each of the plurality of terminals includes a root portion, a first terminal arm and a second terminal arm, the root portion is covered by the terminal base, an end portion of the first terminal arm and an end portion of the second terminal arm extend out of the terminal base.

Preferably, the terminal base forms a plurality of holes, and the plurality of terminals are spaced apart from each other at the corresponding holes.

Preferably, the terminal base contains an insulation material.

Based on the above objects, the present application further provides an electrical connector structure used to connect an optoelectronic transceiver module to a motherboard. The electrical connector structure comprises an intermediate board module and a fixing structure. The intermediate board module includes a plurality of terminal modules, each of the plurality of terminal modules includes a plurality of terminals and a terminal base, the plurality of terminals are spaced apart from each other, and the plurality of terminal modules are arranged side by side. The fixing structure includes a pair of fixing walls, a plurality of first limiting members and a second limiting member. The pair of fixing walls are disposed on the motherboard and are spaced apart from each other to form an accommodating space, the plurality of first limiting members are respectively disposed on the pair of fixing walls and protruding toward the accommodating space, and the second limiting member is located above the first limiting members. The intermediate board module and the optoelectronic transceiver are sequentially stacked and detachably arranged in the accommodating space, the plurality of first limiting members restrict the intermediate board module on the motherboard, the second limiting member restricts the optoelectronic transceiver on the intermediate board module, and the optoelectronic transceiver is connected to the motherboard by the plurality of terminals of the intermediate board module.

Preferably, the intermediate board module further includes a first board and a second board assembled together, the plurality of terminal modules are arranged between the first board and the second board, each of the terminals includes a root portion, a first terminal arm and a second terminal arm, the root portion is fixed in the terminal base, an end portion of the first terminal arm extends out of the first board, and an end portion of the second terminal arm extends out of the second board.

In comparison with the prior art, this application has the following beneficial effects:

In one embodiment provided by the terminal module and the terminal module manufacturing method of the present application, the required number of the terminals can be adjusted by the laser cutting process to produce the terminal module. In another embodiment provided by the terminal module manufacturing method of the present application, the terminals can be formed independently, and the terminal module can be further produced according to the required number of the terminals, without the need for the laser cutting processing. In addition, because the terminals of the present application are manufactured by a stamping process, compared with an existing etching manufacturing method, they have the advantages of stable size, high precision, fast production, and convenient terminal storage and protection. In addition, due to the small size of the terminal modules, they can be arranged side by side to increase terminal density.

In the electrical connector structure of the embodiment of the present invention, the intermediate board module and the optoelectronic transceiver module can be sequentially stacked by the pressure connection way and detachably arranged in the fixing structure, the first limiting member and the second limiting member are used to firmly press the intermediate board module and the optoelectronic transceiver module respectively, so that the optoelectronic transceiver module can be connected to the electrical connector structure by the simple pressure connection way and then directly connected to the motherboard through the integrated terminals of the intermediate board module, and the electrical signals from the optoelectronic transceiver module after optoelectronic conversion can be transmitted to the motherboard, thereby fully utilizing the advantages of high-capacity and high-speed transmission provided by the optoelectronic transceiver module, and shortening the transmission distance between the optoelectronic transceiver module and the motherboard. This effectively solves the problem of long transmission paths and difficulty in maintenance and replacement caused by the prior co-packaged optical components that must be connected to the motherboard through connecting wires and connectors.

### BRIEF DESCRIPTION OF DRAWINGS

FIG. 1 is a schematic view showing that terminals are manufactured by stamping according to one embodiment of the present application.

FIG. 2A is a schematic view of the terminals, which are manufactured by a first terminal module manufacturing method and has one stamping region, according to the present application.

FIG. 2B is a schematic view of the terminals, which are manufactured by the first terminal module manufacturing method and has multiple stamping regions, according to the present application.

FIG. 2C is a process view of the first terminal module manufacturing method according to one embodiment of the present application.

FIG. 2D is a process view of the second terminal module manufacturing method according to one embodiment of the present application.

FIG. 3A is a schematic view of an embedded injection molding process in the first terminal module manufacturing method according to one embodiment of the present application.

FIG. 3B is a schematic view of an embedded injection molding process in the second terminal module manufacturing method according to one embodiment of the present application.

FIG. 4 is a perspective schematic view of a combination of an electrical connector structure and a motherboard according to one embodiment of the present application.

FIG. 5 is an exploded schematic view of the electrical connector structure of FIG. 4.

FIG. 6 is an exploded schematic view of an intermediate board module according to one embodiment of the present application.

FIG. 7 is a partially enlarged schematic view of a terminal module according to one embodiment of the present application.

FIG. 8 is an exploded schematic view of the electrical connector structure and an optoelectronic transceiver module according to one embodiment of the present application.

FIG. 9 is a perspective schematic view of a combination of the electrical connector structure and the optoelectronic transceiver module of FIG. 8.

FIG. 10 is a top view of the electrical connector structure, the optoelectronic transceiver module, and a motherboard of FIG. 9.

FIG. 11 is a sectional view along an A-A line of FIG. 10.

FIG. 12 is a sectional view along a B-B line of FIG. 10.

FIG. 13 is a perspective schematic view of the combination of the electrical connector structure and the optoelectronic transceiver module from the bottom view of FIG. 9.

FIGS. 14A to 14F are process views of connecting the optoelectronic transceiver module to the electrical connector structure of one embodiment of the present application by crimping.

FIG. 15 is a structure schematic view of the terminals in contact with the optoelectronic transceiver module according to one embodiment of the present application.

FIG. 16 is a schematic view of usage states of the electrical connector structure according to one embodiment of the present application.

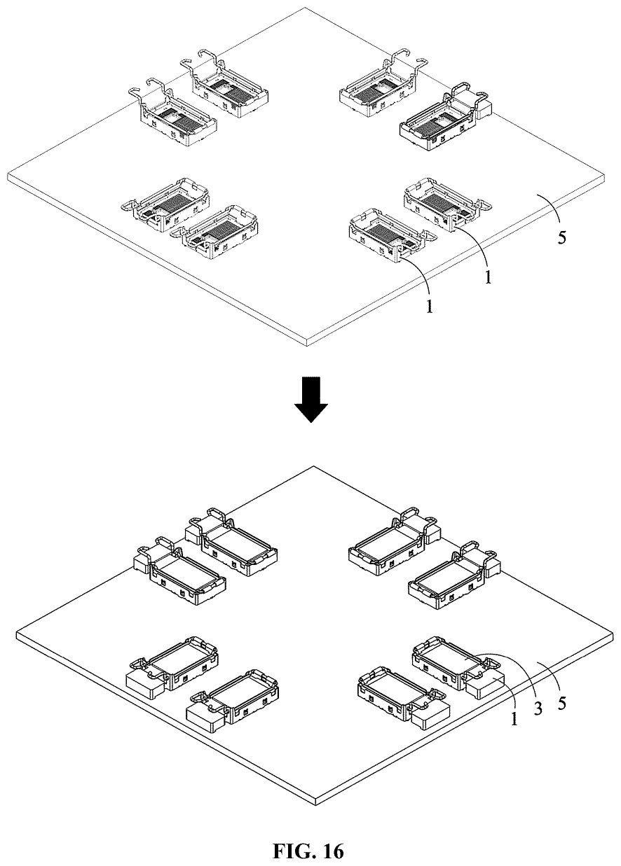

FIG. 17 a flow chart of manufacturing the terminals by etching in the prior art.

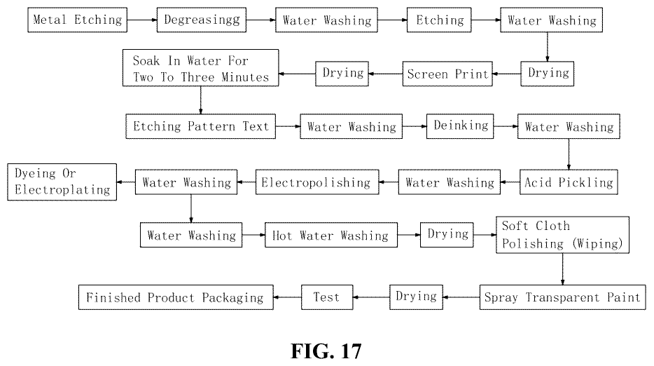

### DETAILED DESCRIPTION OF PREFERRED EMBODIMENTS

Following descriptions of the present application accompanied by drawings being incorporated and forming a part of the specification are used to illustrate embodiments of the present application, but the present application is not limited to the embodiments. In addition, the following embodiments can be appropriately integrated to complete another embodiment.

The following embodiments are illustrated with reference to the accompanying drawings to illustrate the specific embodiments that can be implemented in the present application. Directional terms mentioned in the present application, such as “top”, “bottom”, “front”, “back”, “left”, “right”, “top”, “bottom”, “horizontal”, “vertical”, and etc., are only used with reference to the orientation of the accompanying drawings. Therefore, unless otherwise specified and limited, the used directional terms are intended to illustrate and understand the present application, but not to limit the present application.

As used herein, unless otherwise specified, ordinal adjectives such as “first”, “second”, and “third” used herein to describe a universal object only indicate different instances of similar objects being mentioned, and are not intended to imply that the described objects must be in a given order of time, space, arrangement, or any other method.

In order for the present application to be fully understood, the following description provides detailed steps and structures. Obviously, the implementation of the present application will not limit the specific details known to those skilled in the art. In addition, the known structures and steps will not be described in detail to avoid unnecessary limitations on the present application. It should be noted that the functions or steps mentioned in the description of this application may appear in a different order from those indicated in the accompanying drawings. For example, based on the functions or steps involved, two consecutive figures can actually be executed almost simultaneously or sometimes in reverse order.

The embodiments of the present application provide an electrical connector structure, a terminal module, and a terminal module manufacturing method. The electrical connector structure is used to connect an optoelectronic transceiver module to a motherboard. Furthermore, the terminal of this application is made by a stamping method, which has advantages of high precision, fast speed, low cost, and small size in manufacturing.

Furthermore, in some embodiments, the optoelectronic transceiver module is an Opto-Electronic Integrated Circuit (OEIC) that integrates electronic and photonic integrated circuits, and utilizes a co-packaged technology to form a Co-Packaged Optical (CPO) transceiver module. Preferably, the optoelectronic transceiver module may include at least one light detection element, one light source module, and a plurality of active and passive elements, such as but not limited to filters or multiplexing structures, optical power distribution structures, fiber optic input-output structures, and optical modulation structures. Since features of this application do not involve the structure of the optoelectronic transceiver module known to those skilled in the art, its details are not described in detail here. In some embodiments, the optoelectronic transceiver module connected by the electrical connector structure of the present application has a component structure that conforms to a 3.2 Tb/s co-packaged module implementation protocol specified by the Optical Internetworking Forum (OIF).

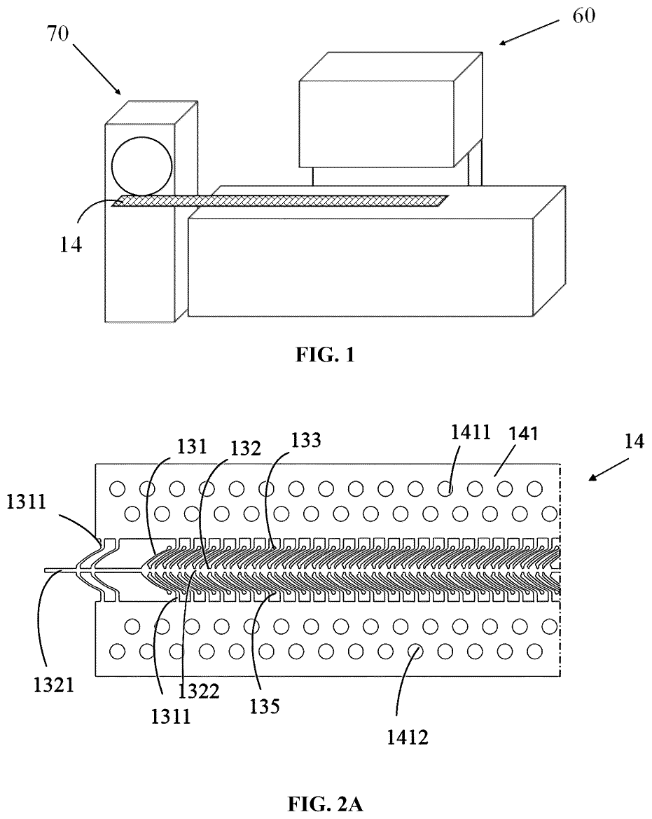

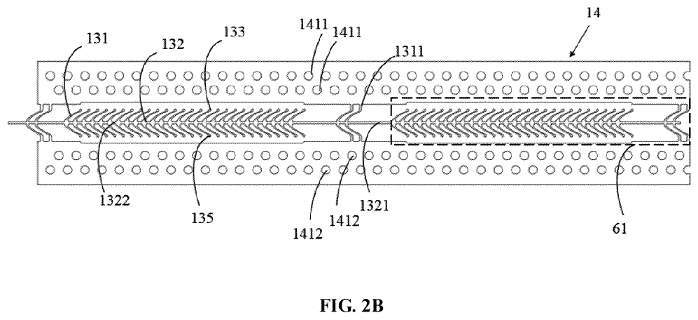

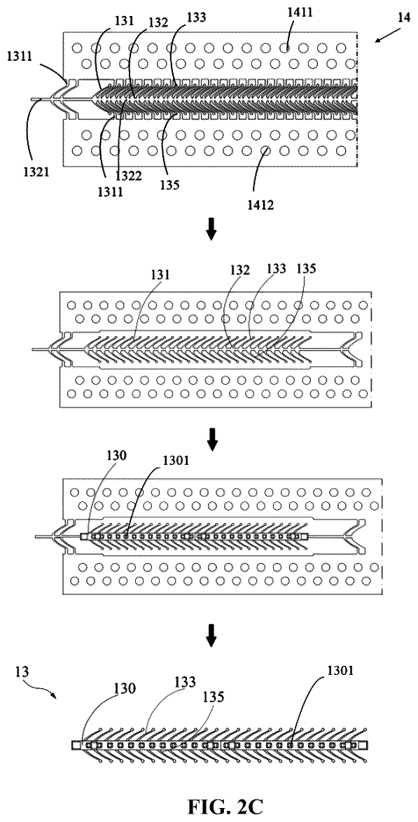

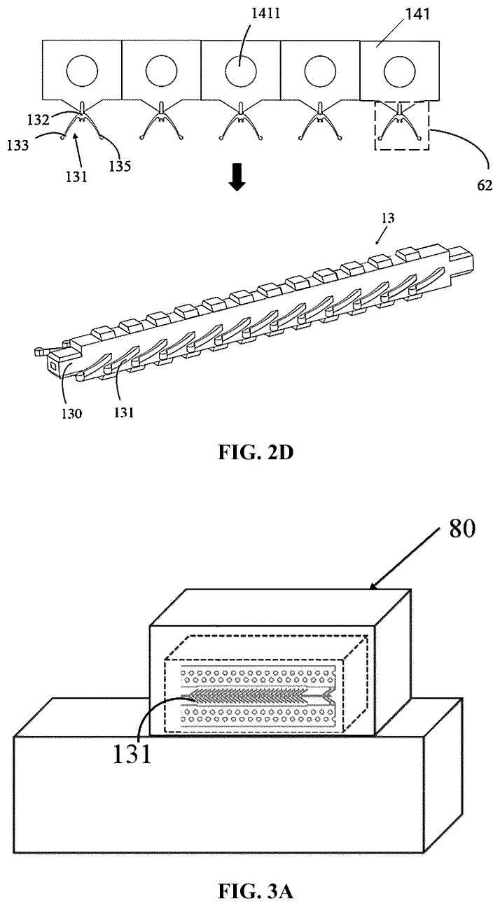

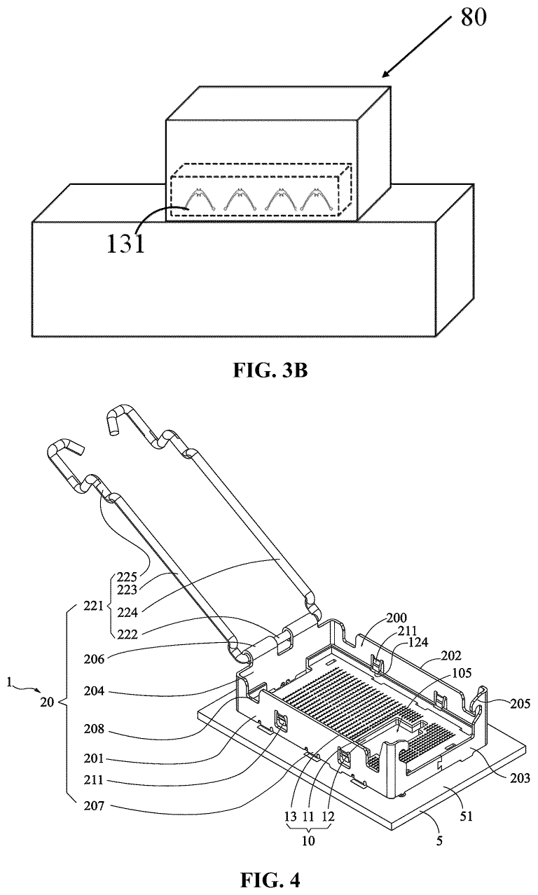

The present application provides a terminal module manufacturing method, which includes:
providing a material strip 14, as shown in FIG. 1;
placing the material strip 14 in a stamping machine 60, as shown in FIG. 1 and FIGS. 2A to 2D;
performing a stamping process on the material strip 14 by the stamping machine 60, and forming a plurality of terminals 131 and at least one material strip fixing portion 141 on the material strip 14, wherein the plurality of terminals 131 is connected to the at least one material strip fixing portion 141; and
forming a terminal base 130 on the plurality of terminals 131, and detaching the plurality of terminals 131 from the at least one material strip fixing portion 141. Alternatively, detaching the plurality of terminals 131 from the at least one material strip fixing portion 141, and then forming the terminal base 130 on the plurality of terminals 131.

Furthermore, the material strip 14 can be made of a thin metal sheet, and in one preferred embodiment, the material strip 14 can be made of beryllium copper alloy, which has advantages of light weight, high strength, and etc. The terminal base 130 contains an insulation material to prevent short circuits between the terminals 131.

In one embodiment, when performing the stamping process on the material strip 14 by the stamping machine 60, the material strip fixing portion 141 is first formed on the material strip 14 for positioning and feeding during a subsequent formation of the terminals 131. Furthermore, in another embodiment, as shown in FIG. 2A, when forming the terminals 131 by the stamping machine 60, a plurality of terminal protection feet 1311 can also be formed together to increase strength and avoid damaging the terminals 131 when the material strip 14 is curled. And in one embodiment, as shown in FIGS. 2A and 2B, some of the terminal protection feet 1311 can be cut by laser and removed to facilitate subsequent processes.

In one embodiment, the present application may use two different methods to stamp and form the terminal module 13. Furthermore, the stamping machine 60 has a stamping tonnage of 50 tons and an accuracy of less than +/−0.01 mm. In a first terminal module manufacturing method, the stamping machine 60 punches about 200 times per minute, and forms two terminals 131 at one time. In a second terminal module manufacturing method, the stamping machine 60 punches about 300 times per minute, and forms one terminal 131 at one time. In other embodiments, the stamping machine 60 may have other stamping tonnages. Depending on a design of a stamping die, the stamping machine 60 can form a larger number of the terminals 131 at one time, for example, three terminals 131 can be formed at one time.

As shown in FIGS. 2A to 2C, in the first terminal module manufacturing method, the terminals 131 are connected to each other by a first connection part 1321 and a plurality of second connection parts 1322. The material strip 14 defines a plurality of stamping regions 61. The plurality of terminals 131 are continuously formed in each of the stamping regions 61 by the stamping die of the stamping machine 60. The terminals 131 of adjacent of the stamping regions 61 is connected by the first connection part 1321. In this embodiment, a length of the first connection part 1321 is greater than that of the second connection part 1322. The length of the second connection part 1322 is 0.5 mm to 0.7 mm, and preferably 0.6 mm, to maintain a spacing between the terminals 131.

In the embodiment where the terminals 131 are connected by the first connection part 1321 and the second connection part 1322, since two terminals 131 are formed at one time, in order to more accurately feed the material strip 14 into the stamping machine 60, the terminal module manufacturing method of the present application may further include: forming a plurality of first positioning holes 1411 on one side of the material strip 14 and a plurality of second positioning holes 1412 on the other side thereof to position the material strip 14 in two directions. Furthermore, a material feeding machine 70 sequentially pushes the material strip 14 in one direction by the first positioning hole 1411 and the second positioning hole 1412 to facilitate the subsequent manufacturing of the terminals 131 by the stamping machine 60.

As shown in FIG. 2D, the second terminal module manufacturing method is to independently manufacture the terminals 131, which will not be connected to each other by the first connection part 1321 and the second connection part 1322 mentioned above. In this embodiment, the material strip 14 still defines a plurality of stamping regions 62. Each terminal 131 is formed in one corresponding stamping region 62. Here, only the plurality of first positioning holes 1411 are formed on one side of the material strip 14, and the material feeding machine 70 may sequentially push the material strip 14 in one direction by the first positioning holes 1411 to facilitate the subsequent manufacturing of the terminals 131 by the stamping machine 60.

In the embodiment of the present application, the terminals 131 are stamped on a metal strip to form an integrated terminal structure. After obtaining a contour of the terminal 131 by stamping, an electroplating process can be performed. Furthermore, prior to the electroplating process, because the terminals 131 are formed from the flexible metal strip, it can be coiled and stored to reduce storage space.

It is worth mentioning that, in one embodiment, the terminals 131 manufactured by the first terminal module manufacturing method can remove unnecessary terminals 131 according to a predetermined number, such as any number from 1 to 30. For example, the first connection part 1321 and/or the second connection part 1322 between the terminals 131 can be cut by laser to obtain the terminals 131 having the predetermined number, and these terminals 131 are connected to each other by the second connection parts 1322. For the terminals 131 manufactured by the second terminal module manufacturing method, the above-mentioned terminal removal step will not be performed because each terminal 131 is independently stamped and formed.

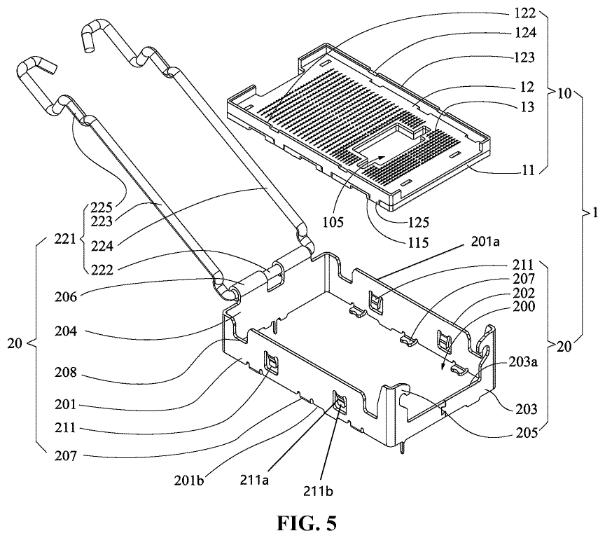

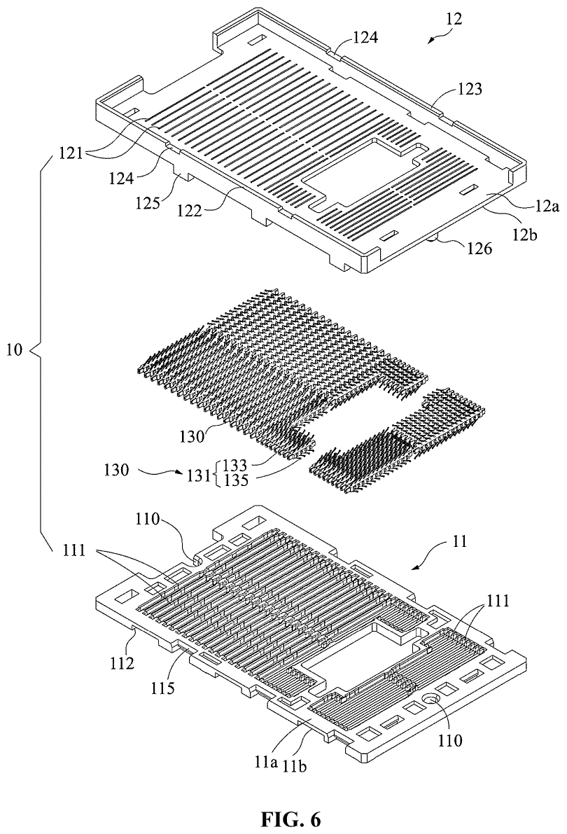

After stamping to obtain the contour of the terminal 131, the terminal module manufacturing method of the present application further includes: electroplating the terminals 131. In one embodiment, the electroplating method includes: first plating nickel on at least one terminal 131, and then plating silver, gold, or palladium on the terminal 131. In one preferred embodiment, the electroplating method further includes a selective plating method or a spray plating method. The selective plating method is to form a plating coat on a desired area of the terminal 131 by electroplating, while the spray plating method is to form a plating coat on the terminal 131 by spraying. After forming the plating coat, the terminal base 130 can be further manufactured on the terminals 131 to form the terminal module 13, which can be assembled with other components to form the electrical connector structure 1 shown in FIG. 3. Furthermore, before forming the terminal base 130, since the terminals 131 are formed by the flexible metal strip, it can be rolled up and stored to reduce the storage space.

After forming the plating coat on the terminal 131, in one embodiment, the terminal module manufacturing method of the present application further includes: forming the terminal base 130 on rows of the terminals 131 by an embedded injection molding process. Furthermore, in one embodiment, the terminal base 130 is made of plastic, and the terminal module manufacturing method of the present application further includes: forming the terminal base 130 on the plurality of terminals 131 by a plastic molding machine 80.

As shown in FIGS. 2C and 3A, for the terminals 131 manufactured by the first terminal module manufacturing method, after the plating coat is formed on the terminal 131, the material strip 14 including the material strip fixing portion 141 and the terminals 131 is disposed in the plastic molding machine 80, and the terminal base 130 can be molded on the terminals 131 by the plastic molding machine 80, and then a laser cutting process is performed.

In one embodiment, the terminal base 130 forms a plurality of holes 1301. The holes 1301 and the terminal base 130 are formed on the terminals 131 together, and are located between the terminals 131 connected to each other.

In order to avoid short circuits between the terminals 131, in the present application, the terminal module manufacturing method further includes: cutting these second connection parts 1322 and the first connection part 1321 connected between the terminals 131 in the same stamping region 61 through these holes 1301 by the laser cutting process, so that the terminals 131 are not connected to each other. Moreover, the terminals 131 can be separated from the material strip fixing portion 141. The method of separating the terminals 131 from the material strip fixing portion 141 can also be the laser cutting process, but can not be limited to this. In this way, it is possible to obtain the terminal base 130 that is combined with the row of terminals 131, and complete the production of the terminal module 13.

It is worth mentioning that a cutting sequence of the first connection part 1321, the second connection part 1322, and a connection of the material strip fixing portion 141 and the terminals 131 is not limited. For example, the first connection part 1321 and the second connection part 1322 can be cut in sequence, and then a connection between the material strip fixing portion 141 and the terminals 131 can be cut, but the cutting sequence can also be changed.

Furthermore, as shown in FIGS. 2D and 3B, for the terminals 131 manufactured by the second terminal module manufacturing method, because the terminals 131 are stamped to be independent each other, they are not connected connected to each other. After the plating coat is formed on the terminals 131, various methods such as automatic mechanical and manual can be used to separate the terminals 131 from the material strip fixing portion 141, and the terminals 131 can be placed in the plastic molding machine 80 according to a required quantity, such as 1 to 100, to facilitate a subsequent embedded injection molding process. This allows the terminal base 130 to be formed on the terminals 131 spaced apart from each other. In this way, the terminal base 130 that is combined with a row of terminals 131 can be obtained, thereby completing the production of the terminal module 13.

It is worth mentioning that if the terminals 131 are manufactured in the first terminal module manufacturing method mentioned above, the laser cutting process is required in the future. However, if the terminals 131 are manufactured in the second terminal module manufacturing method mentioned above, the laser cutting process is not necessary. Therefore, the terminals 131 obtained by the second terminal module manufacturing method mentioned above can save more costs.

In summary, as shown in FIGS. 2C and 2D, the terminal module 13 of the present application includes the plurality of terminals 131 and the terminal base 130. The terminal base 130 covers the terminals 131. Each of the terminals 131 includes a root portion 132, a first terminal arm 133, and a second terminal arm 135. The root portion 132 is covered by the terminal base 130, and an end portion 134 of the first terminal arm 133 and an end portion 136 of the second terminal arm 135 extend out of the terminal base 130.

Moreover, in the terminal module 13 manufactured by the first terminal module manufacturing method, the terminal base 130 forms a plurality of holes 1301, and the plurality of terminals 131 are spaced apart from each other at the corresponding holes 1301 by the laser cutting process described above. In the terminal module 13 manufactured by the second terminal module manufacturing method, each terminal 131 is independently stamped and formed, there is no need to perform the laser cutting process, so the holes 1301 are not required in the terminal base 130.

It should be noted that an intermediate board module 10 of the present application is equipped with thousands of terminals 131, and each terminal 131 is a miniature size in millimeters, so the difficulty of assembling the terminals and terminal base will be greatly increased. By the above stamping process, the terminals 131 are directly formed on a continuous metal strip, and then the terminals 131 are combined with the terminal base 130 by the embedded injection molding process, which can accurately and stably fix the terminals 131 on the terminal base 130, effectively reduce the assembly difficulty and facilitate the subsequent combination of the terminal module 13 and a terminal slot 111.

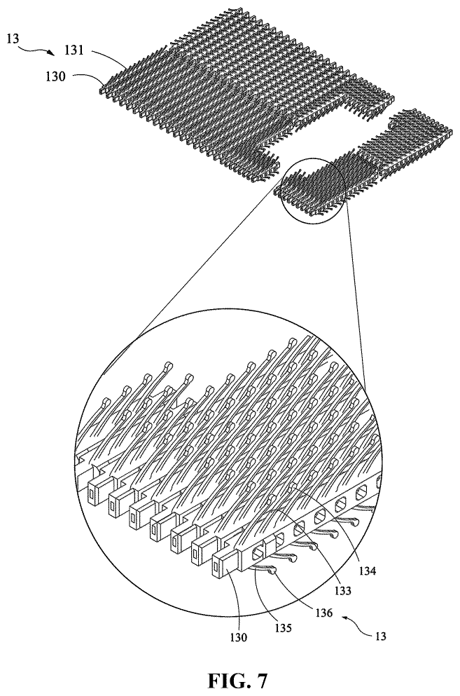

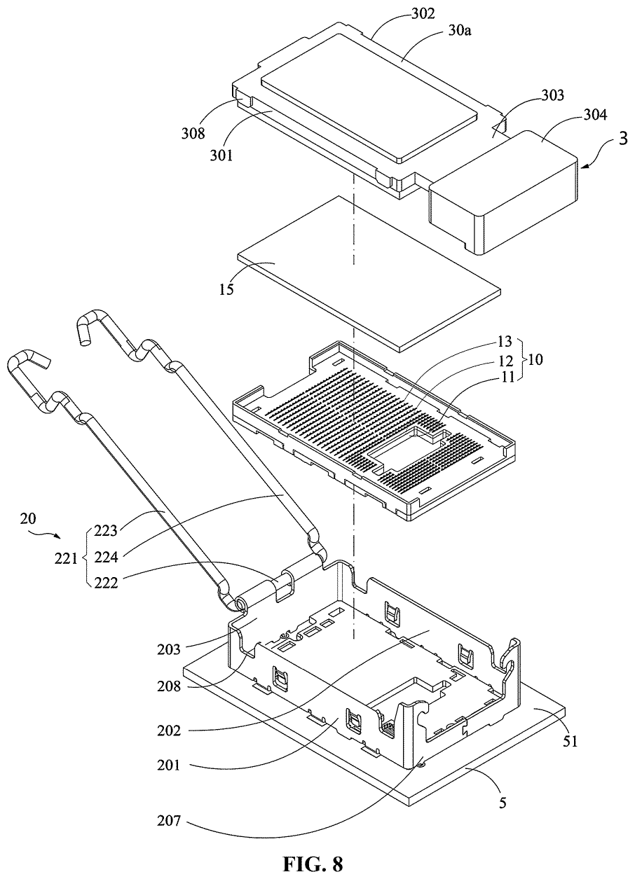

Referring to FIGS. 4 and 5, FIG. 4 is a perspective schematic view of a combination of an electrical connector structure 1 and a motherboard 5 according to one embodiment of the present application, and FIG. 5 is an exploded schematic view of the electrical connector structure 1 of FIG. 4. As shown in FIG. 1, the present application provides the electrical connector structure 1, including an intermediate board module 10 and a fixing structure 20. Specifically, the intermediate board module 10 includes a first board 11 and a second board 12 that can be assembled together and detached from each other, and a plurality of terminal modules 13. Specifically, the second board 12 and the first board 11 are assembled together by stacking up and down. The plurality of terminal modules 13 are arranged between the first board 11 and the second board 12. Each terminal module 13 includes the plurality of terminals 131 and the terminal base 130. The plurality of terminals 131 of each terminal module 13 are spaced apart from each other, and the plurality of terminal modules 13 are arranged side by side. In some embodiment, each terminal 131 includes a root portion 132, a first terminal arm 133 and a second terminal arm 135. The root portion 132 is fixed in the terminal base 130, an end portion 134 of the first terminal arm 133 extends out of the first board 11, and an end portion 136 of the second terminal arm 135 extends out of the second board 11.

It is worth mentioning that, due to a very small size of the terminal module 13 and a parallel arrangement of the terminal modules 13 in the present application, compared to an existing method of assembling metal terminals into an entire plastic body, the parallel arrangement of the terminal modules 13 of the present application can break through the size limitation. The reason is that, in the existing method, if the plastic body is injection molded in one go, a minimum volume of the plastic body will be limited by manufacturing. Therefore, the terminal module 13 of the present application has the possibility of achieving a maximum terminal density.

Please continue to refer to FIG. 4, the fixing structure 20 includes a pair of fixing walls 201 and 202, a front limiting wall 203 and a rear limiting wall 204, a plurality of first limiting members 211, and a second limiting member 221. Specifically, the front limiting wall 203 and the rear limiting wall 204 connect the pair of fixing walls 201 and 202, and form a frame structure together with the pair of fixing walls 201 and 202. The frame structure can be fixed on a surface 51 of a motherboard 5 by a surface adhesion technology, and form an accommodating space 200. In this embodiment, the motherboard 5 is a circuit board that can be equipped with one or a plurality of processors and electronic components (not shown), and is suitable for a motherboard such as a switch or a server. In some embodiments, the fixing walls 201 and 202, a front limiting wall 203 and the rear limiting wall 204 can be made of a material with high hardness characteristics, such as metal materials, preferably stainless steel, and can be formed through a metal stamping process. But the above material and the preparation method are not limited to this. As shown in FIGS. 4 and 5, a stamping process is performed on the fixing walls 201 and 202 to form a plurality of first limiting members 211 as a whole. The plurality of first limiting members 211 protrude into the accommodating space 200 and each first limiting member 211 form an inclined edge 211a and a free end 211b, so that the first limiting members 211 can be displaced outward due to the pressure of an external object in the accommodating space 200. In this embodiment, as shown in FIG. 2, the fixing walls 201 and 202 include a plurality of fixing pieces 207 and limiting grooves 208. Specifically, the limiting grooves 208 are formed at one top edges 201a of the pair of fixing walls 201 and 202. The fixing pieces 207 are disposed at bottoms 201b of the pair of fixing walls 201 and 202, and are bent toward the accommodating space 200 respectively. In this embodiment, the fixing pieces 207 can be fixed on the surface 51 of the motherboard 5 through the surface adhesion technology.

As shown in FIGS. 4 and 5, the intermediate board module 10 is detachably disposed on the motherboard 5. Specifically, the intermediate board module 10 enters the accommodating space 200 from directly above the accommodating space 200 in a downward direction, and interferes with the inclined edge 211a of the first limiting member 211 on two opposite sides during its downward movement, thereby pushing the first limiting member 211 outward. Finally, the intermediate board module 10 passes through the first limiting member 211, the first limiting member 211 returns to its original position, and the free end 211b presses against the intermediate board module 10 and fixes the intermediate board module 10 on the surface 51 of the motherboard 5. Through the above pressure connection way, the intermediate board module 10 can be firmly fixed on the motherboard 5, and the first terminal arms 133 contact corresponding conductive contacts (not shown) of the motherboard 5. When the intermediate board module 10 needs to be detached from the fixing structure 20, the first limiting element 211 can be pushed toward the outside of the accommodating space 200 to remove the intermediate board module 10.

It should be noted that in other embodiments, the fixing structure 20 may only have the pair of fixing walls 201 and 202 without the front limiting wall 203 and the rear limiting wall 204. The fixing walls 201 and 202 can use an inclined support structure (not shown) supported on the motherboard 5 to strengthen the structural strength thereof. By disposing the fixing walls 201 and 202 as described above, the first limiting member 211 can also be used to press and fix the intermediate board module 10.

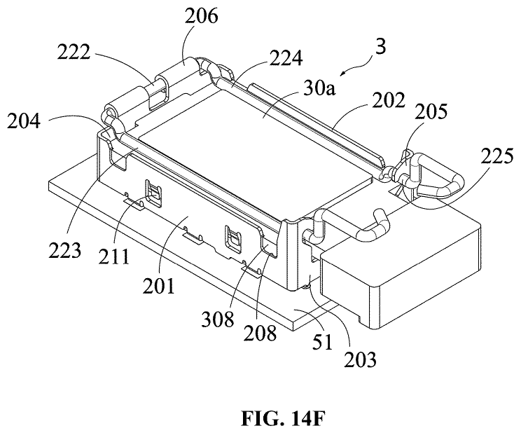

As shown in FIG. 5, the rear limiting wall 204 includes a pivot portion 206 with a shaft hole, and the second limiting member 221 is rotatably connected to the pivot portion 206 and located above the first limit member 211. Specifically, the front limiting wall 203 includes an opening 203a and a pair of holding portions 205. The holding portions 205 are disposed at a top of the front limiting wall 203 and located on two sides of the opening 203a. In some embodiments, each of the pair of holding portions 205 has an inverted hook structure. As shown in FIG. 2, the second limiting member 221 includes a pair of pressure applying rods 223 and 224, and a connecting rod 222 connected between the pair of pressure applying rods 223 and 224. The pressure applying rods 223 and 224 are integrated with the connecting rod 222 to form a U-shaped structure. A material of the second limiting component 221 can be the same as that of the fixing walls 201 and 202. Specifically, the connecting rod 222 is rotatably connected to the pivot portion 206, and rotates around the pivot portion 206 as an axis, thereby driving the pressure applying rods 223 and 224 to rotate between an open state (as shown in FIG. 4) and a holding state (as shown in FIG. 14A) for pressing or releasing a pressure on the optoelectronic transceiver module 3 (as described later). In some embodiment, the pressure applying rods 223 and 224 are extended near the fixing walls 201 and 202. Each of the pressure applying rods 223 and 224 includes an operating portion 225 that extends a predetermined distance outside the holding portion 205 and bends upward to facilitate an operation of a rotation of the pressure applying rods 223 and 224 between the open state and the holding state. When the pressure applying rods 223 and 224 are in the holding state, ends of the pressure applying rods 223 and 224 away from the connecting rod 222 can be movably fixed to the holding portion 205 of the inverted hook structure.

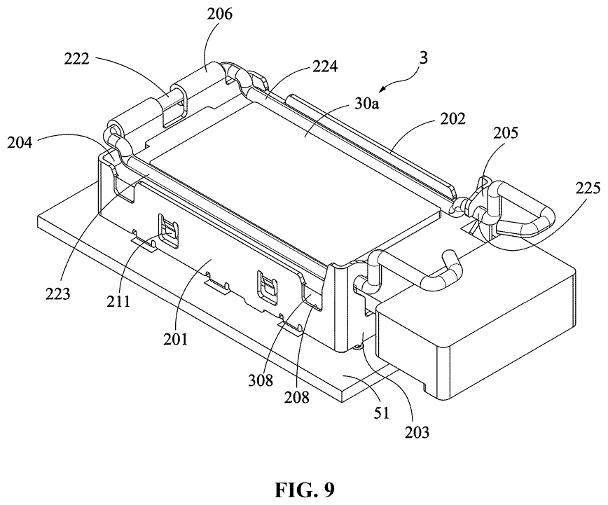

Please refer to FIG. 6, FIG. 6 is an exploded schematic view of the intermediate board module 10 of one embodiment of the present application. As shown in FIGS. 5 and 6, the first board 11 includes a plurality of terminal slots 111 and a plurality of first positioning grooves 112. The terminal slots 111 penetrates an upper surface 11a and a lower surface 11b of the first board 11 in a thickness direction of the first board 11. Specifically, each terminal slot 111 extends toward a width direction of the first board 11, and the plurality of terminal slots 111 are arranged at intervals along a length direction of the first board 11. The second board 12 is detachably assembled to the first board 11 and includes a pair of side walls 122 and 123 and a plurality of through slots 121, and the plurality of through slots 121 are arranged corresponding to the terminal slots 111 and communicate with the terminal slots 111.

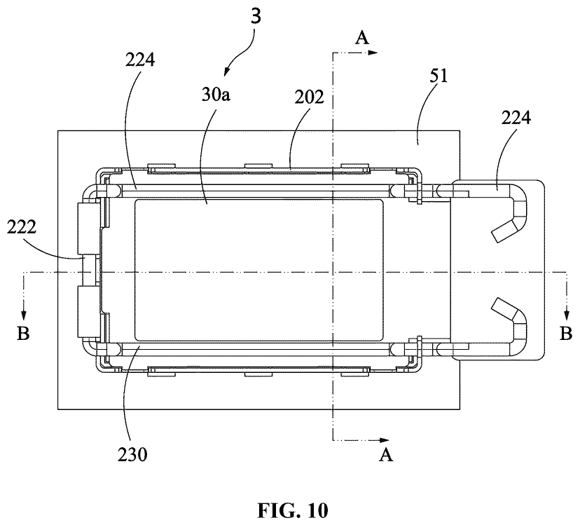

As shown in FIG. 6, the pair of side walls 122 and 123 are spaced apart from each other at a top portion 12a of the second board 12, and are close to and parallel to the fixing walls 201 and 202. Each of the side walls 122 and 123 includes a plurality of second positioning grooves 124, which are distributed at the tops of the side walls 122 and 123. In this embodiment, the first limiting member 211 presses against the corresponding second positioning groove 124 (as shown in FIG. 4) to fix the intermediate board module 10 on the motherboard 5. Moreover, the fixing pieces 207 of the fixing walls 201 and 202 are inserted into the corresponding first positioning grooves 112 to further limit the first board 11 in the length direction. As shown in FIGS. 5 and 6, the terminal base 130 of the terminal module 13 is disposed in the corresponding terminal slot 111 and located between the first board 11 and the second board 12. The end portion 134 (marked in FIG. 7) of the first terminal arm 133 of each terminal 131 extends outside the terminal slot 111, and the end portion 136 (marked in FIG. 7) of the second terminal arm 135 of each terminal 131 extends outside the through slot 121.

Please continue to refer to FIGS. 6 and 7, in some embodiments, the first board 11 includes a plurality of first locking portions 115, and the second board 12 includes a plurality of first locking unit 125, which is detachably engaged with the first locking portion 115. Preferably, the first locking unit 125 is a hook that protrudes downward, and the first locking portion 115 is a groove for the hook to engage. A bottom portion 12b of the second board 12 is attached to the upper surface 11a of the first board 11. The bottom portion 12b of the second board 12 includes a plurality of positioning posts 126, which extend toward the first board 11. The first board 11 further includes a plurality of through holes 110, and the motherboard 5 includes a plurality of positioning holes. The positioning posts 126 respectively pass through the corresponding through holes 110 and are inserted into the corresponding positioning holes to further fix the intermediate board module 10 on the motherboard 5.

Please continue to refer to FIGS. 6 and 7 in conjunction with FIGS. 2A to 2C, the first terminal arm 133 is inclined from the root portion 132 toward the terminal slot 111 of the first board 11 and a middle of the accommodating space 200, and the second terminal arm 135 is inclined from the root portion 132 toward the through slot 121 of the second board 12 and a middle of the accommodating space 200. The first terminal arm 133 and the second terminal arm 135 are symmetrically arranged up and down relative to the root portion 132. In this embodiment, the second terminal arm 135 has an outwardly convex arc-shaped cross-section relative to the terminal base 130, extending from the root portion 132 to the end portion 136 of the second terminal arm 135. The first terminal arm 133 also has an arc-shaped cross-section similar to that of the second terminal arm 135. The terminal base 130 covers the root portion 132. These terminals 131 are aligned in rows and spaced apart from each other on the terminal base 130. In some embodiments, each of the end portions 134 and 136 has a convex arc-shaped contour to facilitate contact with the corresponding conductive contact. It should be noted that the second terminal arm 135 and the first terminal arm 133 can be deformed by an external pressure and can return to their original state when the pressure is released.

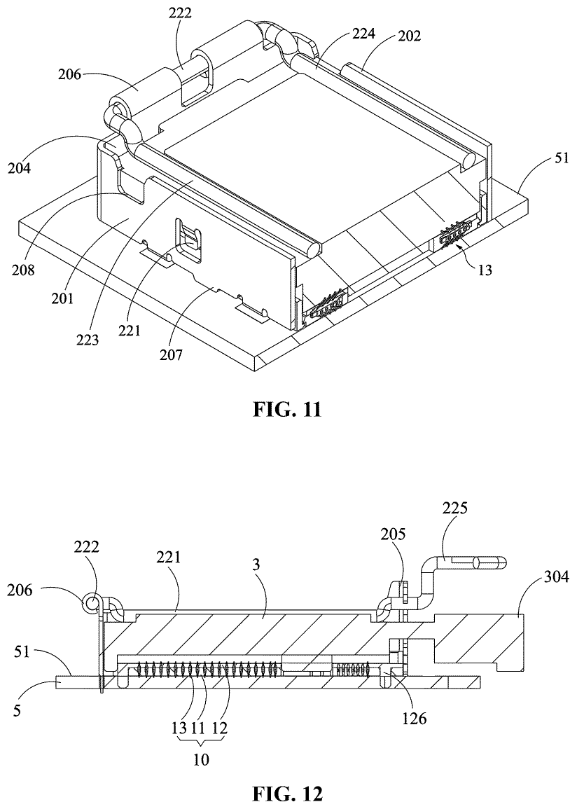

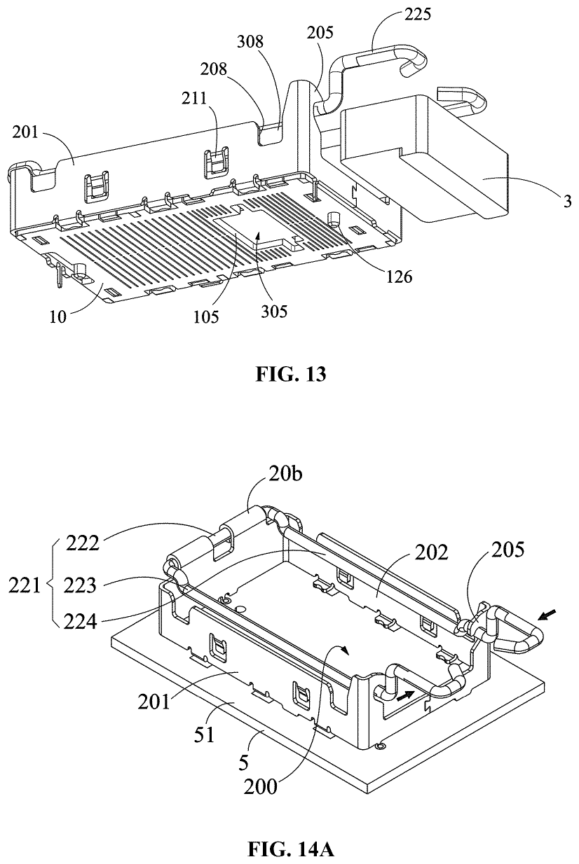

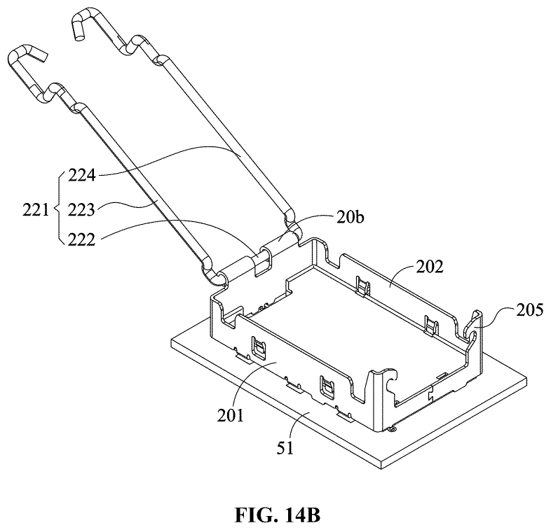

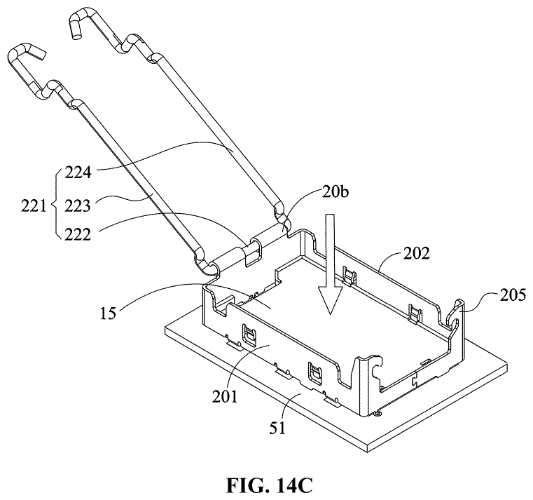

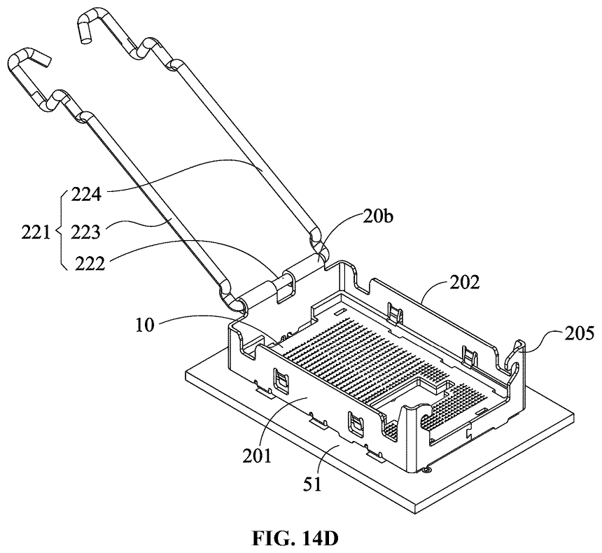

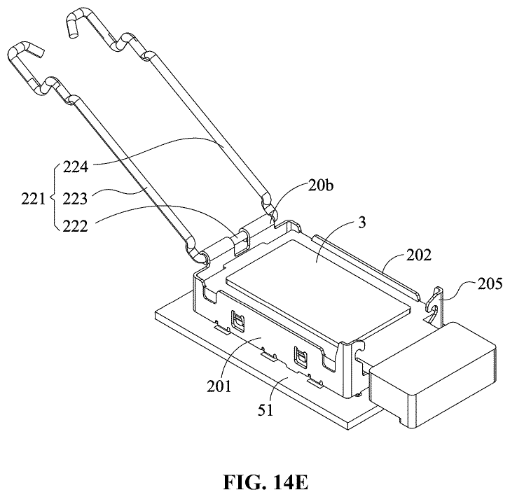

Please refer to FIGS. 8 to 13, FIG. 8 is an exploded schematic view of the electrical connector structure 1 and the optoelectronic transceiver module 3 according to one embodiment of the present application. FIG. 9 is a perspective schematic view of a combination of the electrical connector structure 1 and the optoelectronic transceiver module 3 of FIG. 8. FIG. 10 is a top view of the electrical connector structure 1, the optoelectronic transceiver module 3, and the motherboard 5 of FIG. 9. FIG. 11 is a sectional view along an A-A line of FIG. 10. FIG. 12 is a sectional view along a B-B line of FIG. 10. And FIG. 13 is a perspective schematic view of the combination of the electrical connector structure 1 and the optoelectronic transceiver module 3 of FIG. 9 from a bottom perspective. As shown in FIG. 8, the electrical connector structure 1 of the embodiment of the present application further includes a protective cover plate 15, which removably covers the top portion 12a of the second board 12 to protect the exposed terminals 131 during assembly. In some embodiments, as shown in FIG. 8, the optoelectronic transceiver module 3 includes a top portion 30a, two opposite sides 301 and 302, a neck portion 303, a connecting head 304 and a plurality of limiting protrusions 308. In some embodiments, the connecting head 304 is used to connect multiple optical fibers (not shown) or cables (not shown) to transmit and receive optical signals or electrical signals. Specifically, the limiting protrusions 308 are disposed on the opposite sides 301 and 302 of the optoelectronic transceiver module 3. After the intermediate board module 10 enters the accommodating space 200 and is fixed on the motherboard 5 by the pressure connection way, the protective cover plate 15 is removed, and the optoelectronic transceiver module 3 is detachably disposed on the intermediate board module 10 by the pressure connection way, wherein the limiting protrusions 308 can be detachably engaged with the limiting groove 208 of the fixing walls 201 and 202, as shown in FIG. 9.

As shown in FIGS. 11 and 12, after the optoelectronic transceiver module 3 is fixed by the pressure connection way, the pressure applying rods 223 and 224 of the second limiting member 221 presses against the top portion 30a of the optoelectronic transceiver module 3, and a bottom portion of the optoelectronic transceiver module 3 is located between the fixing walls 201 and 202. The optoelectronic transceiver module 3 is electrically connected to the motherboard 5 through the plurality of terminals 131 of the intermediate board module 10. As shown in FIG. 13, the bottom portion of the optoelectronic transceiver module 3 includes a positioning protrusion 305, the intermediate board module includes a hollow portion 105, and the positioning protrusion 305 is inserted into the hollow portion 105 for further fixing the optoelectronic transceiver module 3 and the intermediate board module 10 on the motherboard 5.

Please refer to FIGS. 14A to 14F, FIGS. 14A to 14F are process views of connecting the optoelectronic transceiver module 3 to the electrical connector structure 1 by a pressure connection way. When connecting, first the fixing structure 20 is assembled at a predetermined position on the motherboard 5 (as shown in FIG. 14A), and then the second limiting member 221 is lifted to the open state (as shown in FIG. 14B). Afterwards, the protective cover plate 15 is used to press the intermediate board module 10 downwards from above the motherboard 5 into the accommodating space 200, and the intermediate board module 10 is pressed against the surface 51 of the motherboard 5 through the first limiting member 211 (as shown in FIG. 14C). After positioning the intermediate board module 10, the protective cover plate 15 is removed (as shown in FIG. 14D), the optoelectronic transceiver module 3 is placed into the accommodating space 200 from top to bottom, and the limiting protrusion 308 is fitted into the limiting groove 208 (as shown in FIG. 14E). Finally, the second limiting member 221 is returned to the holding state (as shown in FIG. 14F), and the ends of the pressure applying rods 223 and 224 away from the connecting rod 222 is held in the holding portion 205 of the inverted hook structure. At this time, the pressure applying rods 223 and 224 press against the top portion 30a of the optoelectronic transceiver module 3, thereby completing a connection between the optoelectronic transceiver module 3 and the intermediate board module 10, so that the optoelectronic transceiver module 3 can be electrically connected to the motherboard 5 through the plurality of terminals 131 of the intermediate board module 10. Similarly, when the optoelectronic transceiver module 3 is needed to taken out, it is needed to perform the above reversed steps, the second limiting member 221 is lifted to the open state, and then the optoelectronic transceiver module 3 can be taken out.

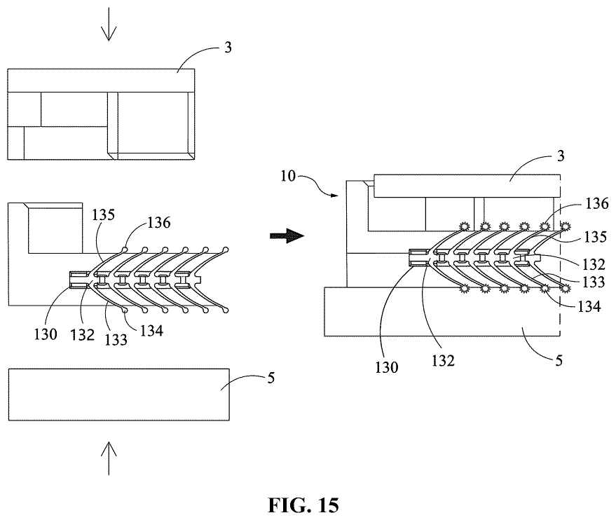

Please refer to FIG. 15, FIG. 15 is a structure schematic view of the terminals 131 in contact with the optoelectronic transceiver module 3. As shown in FIG. 15, when the optoelectronic transceiver module 3 is pressed against the second board 12 from top to bottom, conductive contacts (not shown) at a bottom of the optoelectronic transceiver module 3 contact the corresponding end portions 136 of the second terminal arms 135 and force the second terminal arms 135 to move downward, so that each terminal 131 can be reliably connected to the corresponding conductive contact.

Please refer to FIG. 6, which is a schematic view of a usage state of the electrical connector structure 1 according to one embodiment of the present application. As shown in FIG. 6, a middle of the motherboard 5 may be provided with electronic components such as a processor (not shown), and multiple sets of the electrical connector structures 1 and the optoelectronic transceiver modules 3 may be configured around the motherboard 5. The actual number of the electrical connector structures 1 and the optoelectronic transceiver modules 3 can be determined as needed and can not be particularly limited. Each optoelectronic transceiver module 3 is connected to external signal transmission components, such as optical fibers or cables (not shown). The above structure can handle high-capacity signal transmission and reception to meet requirements of high-speed and large-scale signal processing.

As described above, in one embodiment provided by the terminal module manufacturing method of the present application, the required number of the terminals can be adjusted by the laser cutting process to produce the terminal module. In another embodiment provided by the terminal module manufacturing method of the present application, the terminals can be formed independently, and the terminal module can be further produced according to the required number of the terminals, without the need for the laser cutting processing. In addition, because the terminals of the present application are manufactured by a stamping process, compared with an existing etching manufacturing method, they have the advantages of stable size, high precision, fast production, and convenient terminal storage and protection. In addition, due to the small size of the terminal modules, they can be arranged side by side to increase terminal density.

In the electrical connector structure of the embodiment of the present invention, the intermediate board module and the optoelectronic transceiver module can be sequentially stacked by the pressure connection way and detachably arranged in the fixing structure, the first limiting member and the second limiting member are used to firmly press the intermediate board module and the optoelectronic transceiver module respectively, so that the optoelectronic transceiver module can be connected to the electrical connector structure by the simple pressure connection way and then directly connected to the motherboard through the integrated terminals of the intermediate board module, and the electrical signals from the optoelectronic transceiver module after optoelectronic conversion can be transmitted to the motherboard, thereby fully utilizing the advantages of high-capacity and high-speed transmission provided by the optoelectronic transceiver module, and shortening the transmission distance between the optoelectronic transceiver module and the motherboard, and facilitating maintenance and replacement. This effectively solves the problem of long transmission paths and difficulty in maintenance and replacement caused by the prior co-packaged optical components that must be connected to the motherboard through connecting wires and connectors.

The above descriptions are for illustrative purposes only and not restrictive. For those skilled in the art, there will be changes in the specific implementation and application scope based on the ideas of the present application. In summary, the contents of this specification should not be construed as a limitation of this application.

What is claimed is:

1. A terminal module manufacturing method, comprising:
providing a material strip;
forming a plurality of terminals and at least one material strip fixing portion on the material strip by a stamping process; wherein the plurality of terminals is connected to the at least one material strip fixing portion; and
forming a terminal base on the plurality of terminals, and then detaching the plurality of terminals from the at least one material strip fixing portion; or
detaching the plurality of terminals from the at least one material strip fixing portion, and then forming the terminal base on the plurality of terminals.

2. The terminal module manufacturing method according to claim 1, wherein the terminal base is made of plastic; and
the terminal module manufacturing method further comprises: disposing the plurality of terminals and the at least one material strip fixing portion in a plastic molding machine to form the terminal base.

3. The terminal module manufacturing method according to claim 2, wherein the material strip defines a plurality of stamping regions; and
the terminal module manufacturing method further comprises: forming the plurality of terminals in each of the plurality of stamping regions, wherein the plurality of terminals between the plurality of stamping regions are connected by a first connection part.

4. The terminal module manufacturing method according to claim 3, further comprising: after forming the terminal base on the plurality of terminals, cutting the first connection part and a connection between the plurality of terminals and the at least one material strip fixing portion.

5. The terminal module manufacturing method according to claim 3, further comprising: according to a predetermined number, cutting the first connection part and removing unnecessary of the terminals by laser to obtain the plurality of terminals having the predetermined number being connected to each other.

6. The terminal module manufacturing method according to claim 3, wherein the terminal base forms a plurality of holes, which are located between the plurality of terminals connected to each other; and
the terminal module manufacturing method further comprises: cutting a plurality of second connection parts connected between the plurality of terminals in the same stamping region through the plurality of holes by a laser cutting process.

7. The terminal module manufacturing method according to claim 2, wherein the material strip defines a plurality of stamping regions; and
the terminal module manufacturing method further comprises: forming the plurality of terminals in the plurality of stamping regions respectively.

8. The terminal module manufacturing method according to claim 7, further comprising: detaching the plurality of terminals from the at least one material strip fixing portion, and then employing the plastic molding machine to form the terminal base on the plurality of terminals spaced apart from each other.

9. A terminal module, comprising:
a plurality of terminals; and
a terminal base covering the plurality of terminals;
wherein each of the plurality of terminals includes a root portion, a first terminal arm and a second terminal arm, the root portion is covered by the terminal base, an end portion of the first terminal arm and an end portion of the second terminal arm extend out of the terminal base.

10. The terminal module according to claim 9, wherein the terminal base forms a plurality of holes, and the plurality of terminals are spaced apart from each other at the corresponding holes.

11. The terminal module according to claim 9, wherein the terminal base contains an insulation material.

12. An electrical connector structure, being used to connect an optoelectronic transceiver module to a motherboard, and comprising:
an intermediate board module including a plurality of terminal modules, each of the plurality of terminal modules including a plurality of terminals and a terminal base, the plurality of terminals being spaced apart from each other, and the plurality of terminal modules being arranged side by side; and
a fixing structure including a pair of fixing walls, a plurality of first limiting members and a second limiting member, the pair of fixing walls being disposed on the motherboard and being spaced apart from each other to form an accommodating space, the plurality of first limiting members being respectively disposed on the pair of fixing walls and protruding toward the accommodating space, and the second limiting member being located above the first limiting members;
wherein the intermediate board module and the optoelectronic transceiver are sequentially stacked and detachably arranged in the accommodating space, the plurality of first limiting members restrict the intermediate board module on the motherboard, the second limiting member restricts the optoelectronic transceiver on the intermediate board module, and the optoelectronic transceiver is connected to the motherboard by the plurality of terminals of the intermediate board module.

13. The electrical connector structure according to claim 12, wherein the intermediate board module further includes a first board and a second board assembled together, the plurality of terminal modules are arranged between the first board and the second board, each of the terminals includes a root portion, a first terminal arm and a second terminal arm, the root portion is fixed in the terminal base, an end portion of the first terminal arm extends out of the first board, and an end portion of the second terminal arm extends out of the second board.
